(19) United States
(12) Patent Application Publication
(10) Pub. No.: US 2025/0216614 A1
(43) Pub. Date: Jul. 3, 2025

(54) WIRING SUBSTRATE

(71) Applicant: IBIDEN CO., LTD., Ogaki (JP)

(72) Inventor: Masatoshi KUNIEDA, Ibi-gun (JP)

(73) Assignee: IBIDEN CO., LTD., Ogaki (JP)

(21) Appl. No.: 19/082,953

(22) Filed: Mar. 18, 2025

Related U.S. Application Data
(63) Continuation of application No. PCT/JP2023/033607, filed on Sep. 14, 2023.

(30) Foreign Application Priority Data
Sep. 20, 2022 (JP) 2022-149456

(51) Int. Cl. G02B 6/36; H01L 23/498; H05K 1/02

(52) U.S. Cl. CPC G02B 6/3608; H01L 23/49816; H01L 23/49827; H05K 1/0274; H05K 2201/068; H05K 2201/10121; H05K 2201/10734; H05K 2201/2081

(57) ABSTRACT

A wiring substrate includes an electrical wiring part including insulating layers and conductor layers, and an optical wiring part positioned on a surface of the electrical wiring part and including a support substrate and an optical waveguide such that the optical wiring part has a component region configured to position a component on the optical wiring part and the optical waveguide includes a core part and a cladding part. The support substrate in the optical wiring part has a thermal expansion coefficient lower than a thermal expansion coefficient of the optical waveguide and includes a conductor region and a non-conductor region such that the optical waveguide is formed on a surface of the support substrate in the non-conductor region and the optical wiring part includes one or more penetrating conductors penetrating through the support substrate in the conductor region.

### CROSS-REFERENCE TO RELATED APPLICATIONS

The present application is a continuation of and claims the benefit of priority to International Application No. PCT/JP2023/033607, filed Sep. 14, 2023, which is based upon and claims the benefit of priority to Japanese Application No. 2022-149456, filed Sep. 20, 2022. The entire contents of these applications are incorporated herein by reference.

### BACKGROUND OF THE INVENTION

### Field of the Invention

The present invention relates to a wiring substrate.

### Description of Background Art

Japanese Patent Application Laid-Open Publication No. 2008-129385 describes an optical component mounting substrate, on a surface of which an optical waveguide is mounted. The entire contents of this publication are incorporated herein by reference.

### SUMMARY OF THE INVENTION

According to one aspect of the present invention, a wiring substrate includes an electrical wiring part including insulating layers and conductor layers, and an optical wiring part positioned on a surface of the electrical wiring part and including a support substrate and an optical waveguide such that the optical wiring part has a component region configured to position a component on the optical wiring part and the optical waveguide includes a core part and a cladding part. The support substrate in the optical wiring part has a thermal expansion coefficient lower than a thermal expansion coefficient of the optical waveguide and includes a conductor region and a non-conductor region such that the optical waveguide is formed on a surface of the support substrate in the non-conductor region and the optical wiring part includes one or more penetrating conductors penetrating through the support substrate in the conductor region.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a cross-sectional view illustrating an example of a wiring substrate according to an embodiment of the present invention;

FIG. 2 is an enlarged view of a portion (II) of FIG. 1;

FIG. 3 is a plan view illustrating an example of an optical wiring part of FIG. 1 in a plan view;

FIG. 4A is a cross-sectional view illustrating another example of an optical wiring part in a wiring substrate according to an embodiment of the present invention;

FIG. 4B is a cross-sectional view illustrating another example of an optical wiring part in a wiring substrate according to an embodiment of the present invention;

FIG. 4C is a cross-sectional view illustrating another example of an optical wiring part in a wiring substrate according to an embodiment of the present invention;

FIG. 4D is a cross-sectional view illustrating another example of an optical wiring part in a wiring substrate according to an embodiment of the present invention;

FIG. 5 is a plan view illustrating an example of the optical wiring part of FIG. 4A in a plan view;

FIG. 6 is a cross-sectional view illustrating another example of a penetrating conductor in a wiring substrate according to an embodiment of the present invention;

FIG. 7A is a cross-sectional view illustrating an example of a manufacturing process of an optical wiring part in a wiring substrate according to an embodiment of the present invention;

FIG. 7B is a cross-sectional view illustrating an example of a manufacturing process of an optical wiring part in a wiring substrate according to an embodiment of the present invention;

FIG. 7C is a cross-sectional view illustrating an example of a manufacturing process of an optical wiring part in a wiring substrate according to an embodiment of the present invention;

FIG. 7D is a cross-sectional view illustrating an example of a manufacturing process of an optical wiring part in a wiring substrate according to an embodiment of the present invention;

FIG. 7E is a cross-sectional view illustrating an example of a manufacturing process of an optical wiring part in a wiring substrate according to an embodiment of the present invention;

FIG. 7F is a cross-sectional view illustrating an example of a manufacturing process of a wiring substrate according to an embodiment of the present invention;

FIG. 7G is a cross-sectional view illustrating an example of a process of mounting components after completion of a wiring substrate according to an embodiment of the present invention;

FIG. 8A is a cross-sectional view illustrating a modified example of a wiring substrate according to an embodiment of the present invention; and

FIG. 8B is a cross-sectional view illustrating a modified example of formation of penetrating conductors in a wiring substrate according to an embodiment of the present invention.

### DETAILED DESCRIPTION OF THE EMBODIMENTS

Embodiments will now be described with reference to the accompanying drawings, wherein like reference numerals designate corresponding or identical elements throughout the various drawings.

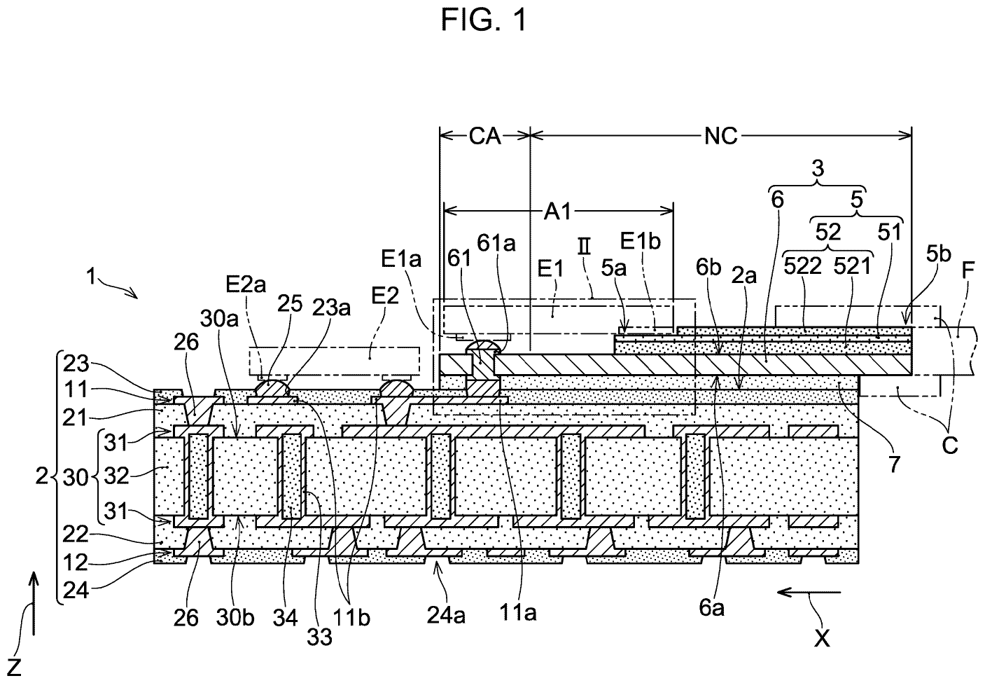

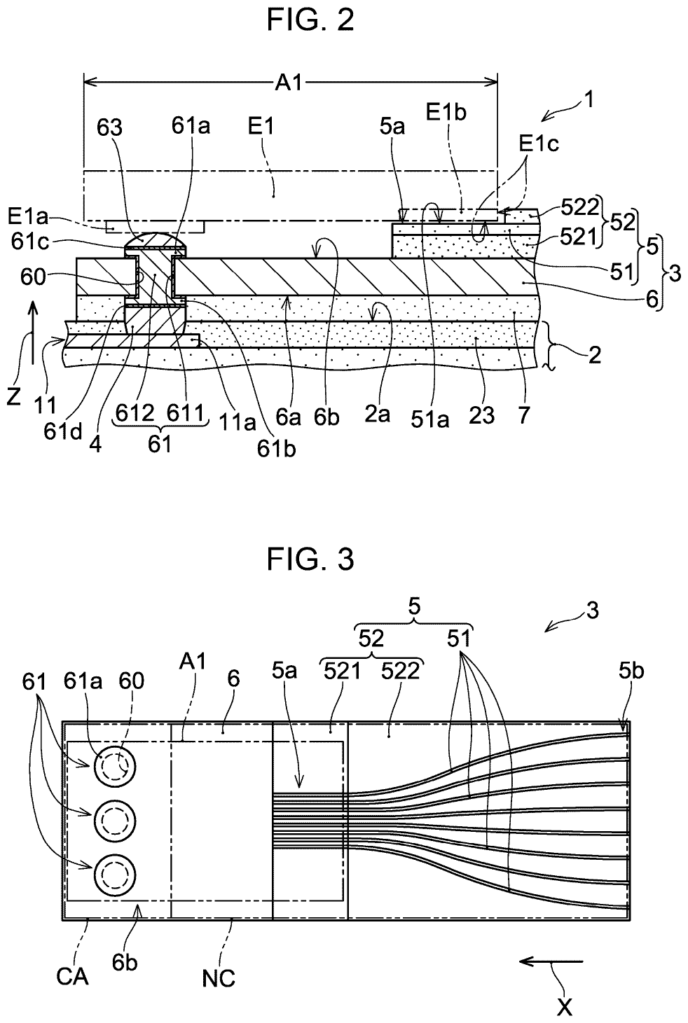

A wiring substrate according to an embodiment of the present invention is described with reference to the drawings. FIG. 1 is a cross-sectional view illustrating a wiring substrate 1, which is an example of the wiring substrate of the embodiment. FIG. 2 illustrates an enlarged view of a portion (II) of FIG. 1. FIG. 3 illustrates an example of an optical wiring part included in the wiring substrate 1 in FIG. 1 in a plan view. The term “plan view” means viewing the wiring substrate of the embodiment along a thickness direction thereof. The wiring substrate 1 is merely an example of the wiring substrate of the present embodiment. A laminated structure, and the number of conductor layers and the number of insulating layers of the wiring substrate of the embodiment are not limited to the laminated structure of the wiring substrate 1 of FIG. 1, and the number of conductor layers and the number of insulating layers included in the wiring substrate 1. Further, in the drawings to be referenced in the following description, in order to facilitate understanding of an embodiment to be described, a specific portion may be depicted in an enlarged manner and it may be possible that structural elements are not depicted in precise proportions in terms of size or length relative to each other.

As illustrated in FIG. 1, the wiring substrate 1 includes an electrical wiring part 2 and an optical wiring part 3 placed on a surface (2a) of the electrical wiring part 2. The electrical wiring part 2 includes insulating layers and conductor layers. Specifically, the electrical wiring part 2 in the example of FIG. 1 includes: a core substrate 30 that has two surfaces (30a, 30b) opposing each other in a thickness direction thereof; an insulating layer 21 and a conductor layer 11 that are sequentially laminated on the surface (3a) of the core substrate 30; and an insulating layer 22 and a conductor layer 12 that are sequentially laminated on the surface (30b) of the core substrate 30. In each of the insulating layer 21 and the insulating layer 22, via conductors 26 connecting the conductor layers that sandwich the insulating layer 21 or the insulating layer 22 to each other are formed. The core substrate 30 includes an insulating layer 32, and conductor layers 31 that are respectively formed on both sides of the insulating layer 32. The insulating layer 32 is provided with through-hole conductors 33 that penetrate the insulating layer 32 and connects the conductor layers 31 on both sides of the insulating layer 32 to each other. Inner sides of the tubular through-hole conductors 33 are filled with, for example, a filler 34 formed of an insulating resin such as an epoxy resin, or a conductive resin containing metal particles.

In the description of the embodiment, a side farther from the insulating layer 32 in the thickness direction of the wiring substrate 1 is also referred to as an “upper side” or simply “upper,” and a side closer to the insulating layer 32 is also referred to as a “lower side” or simply “lower.” Further, for the conductor layers and the insulating layers, a surface facing an opposite side with respect to the insulating layer 32 is also referred to as an “upper surface,” and a surface facing the insulating layer 32 side is also referred to as a “lower surface.” The thickness direction of the wiring substrate 1 is also referred to as a “Z direction.”

The electrical wiring part 2 includes a solder resist 23 formed on the surface (30a) side of the core substrate 30, and a solder resist 24 formed on the surface (30b) side of the core substrate 30. The surface (2a) of the electrical wiring part 2 is mainly formed an upper surface of the solder resist 23. The solder resist 23 partially covers the insulating layer 21 and the conductor layer 11, and the solder resist 24 partially covers the insulating layer 22 and the conductor layer 12. The solder resist 23 has openings (23a) that each expose a portion of the conductor layer 11. Similarly, the solder resist 24 also has openings (24a).

The electrical wiring part 2 includes conductive bumps 25 that are formed in the openings (23a) of the solder resist 23 so as to be in contact with the conductor layer 11. The conductive bumps 25 are formed, for example, using tin-based solder, gold-based solder, or the like. The conductive bumps 25 are used to electrically and mechanically connect electrodes (E2a) of an external component (E2) mounted on the wiring substrate 1 to the portions of the conductor layer 11 exposed to the openings (23a).

The insulating layers (21, 22) and the insulating layer 32 can be formed, for example, using a thermosetting insulating resin such as an epoxy resin, a bismaleimide triazine resin (BT resin), or a phenol resin. The insulating layers (21, 22) and the insulating layer 32 may also be formed using a thermoplastic insulating resin such as a fluororesin, a liquid crystal polymer (LCP), a fluorinated ethylene (PTFE) resin, a polyester (PE) resin, or a modified polyimide (MPI) resin. Although not illustrated, the insulating layers each may contain a core material (reinforcing material) formed of a glass fiber, an aramid fiber, or the like, and each may contain an inorganic filler formed of fine particles of silica (SiO2), alumina, mullite, or the like. On the other hand, the solder resists (23, 24) are formed of, for example, a photosensitive epoxy resin, a photosensitive polyimide resin, or the like.

The conductor layers (11, 12), the conductor layers 31, the through-hole conductors 33, and the via conductors 26 can be formed using any metal such as copper or nickel. In FIG. 1, these conductors are simplified and depicted as each having a one-layer structure. However, these conductors may each have a multilayer structure including two or more films. For example, the conductor layers (11, 12) may each have a two-layer structure including an electroless plating film and an electrolytic plating film. A metal used in electrical wirings formed in the wiring substrate 1 is referred to as a “conductor.”

The conductor layers (11, 12) and the conductor layers 31 may each include any conductor patterns. In the example of FIG. 1, the conductor layer 11 includes conductor pads (11a, 11b). The conductor pads (11a, 11b) are exposed in the openings (23a) of the solder resist 23. In this way, the electrical wiring part 2 in FIG. 1 has conductors exposed on the surface (2a), such as the conductor pads (11a, 11b). The electrodes (E2a) of the component (E2) are connected to the conductor pads (11b) via the conductive bumps 25.

When the wiring substrate 1 is used, as illustrated in FIGS. 1-3, a component (E1) is also mounted. Therefore, the surface (2a) of the electrical wiring part 2 has a component region (A1), which is covered by the component (E1) in a plan view when the wiring substrate 1 is used. The component (E1) mounted in the component region (A1) is an electrical component that includes a light receiving element and/or a light emitting element and has a photoelectric conversion function. The component (E1) in the example of FIGS. 1-3 includes electrodes (Ela) and a light receiving or light emitting part (E1b). The light receiving or light emitting part (E1b) has a light receiving or light emitting surface (E1c) (see FIG. 2) facing sideways and downward from the component (E1). The electrodes (Ela) and the light receiving or light emitting part (E1b) are provided on a surface of the component (E1) facing the wiring substrate 1 side. That is, in the example of FIGS. 1-3, the component (E1) is mounted by so-called face-down mounting (flip-chip mounting).

Examples of the component (E1) include light receiving elements such as a photodiode; and light emitting elements such as a light emitting diode (LED), an organic light emitting diode (OLED), a laser diode (LD), and a vertical cavity surface emitting laser (VCSEL). When the component (E1) is a light emitting element, the component (E1) generates an optical signal based on an electrical signal input to the electrodes (Ela) and emits the optical signal from the light receiving or light emitting part (E1b) functioning as a light emitting part. Further, when the component (E1) is a light receiving element, an electrical signal is generated based on an optical signal input to the light receiving or light emitting part (E1b) functioning as a light receiving part, and is output from the electrodes (E1a).

The component (E2) may be, for example, an electronic component such as a semiconductor device that generates an electrical signal that causes the component (E1) to emit light, and/or processes an electrical signal generated by the component (E1). Examples of the component (E2) include semiconductor devices such as a general-purpose operational amplifier, a driver IC, a microcomputer, and a programmable logic device (PLD).

The optical wiring part 3 positioned on the electrical wiring part 2 includes a support substrate 6 and an optical waveguide 5. The support substrate 6 is positioned via a connecting material 7 on the upper surface of the solder resist 23 that forms the surface (2a) of the electrical wiring part 2. The support substrate 6 includes a conductor region (CA), which has a conductor, and a non-conductor region (NC). The support substrate 6 has a first surface (6b), which is on the component region (A1) side where the component (E1) is positioned, and a second surface (6a), which is on an opposite side with respect to the first surface (6b) and faces the electrical wiring part 2. In the present embodiment, the support substrate 6 has a thermal expansion coefficient lower than that of the optical waveguide 5. The conductor region (CA) includes penetrating conductors 61 penetrating between the first surface (6b) and the second surface (6a) as conductors of the support substrate 6.

The penetrating conductors 61 are formed of any conductive material. The penetrating conductors 61 may contain, for example, metals such as copper, nickel, aluminum, tin, and gold, either individually or in combination. The penetrating conductors 61 may also be solidified bodies of a conductive paste formed of a resin, such as an epoxy resin, containing conductive particles such as silver or copper particles. Along through holes 60 of the penetrating conductors 61 (see FIG. 2), after forming an insulating layer, a plating film may be formed. The penetrating conductors 61 may be filled with a conductive material, or a conductive material may be formed along inner walls of outer peripheral parts of the through holes 60, with centers thereof being hollow. As long as electrical conduction is obtained between the front and back sides of the support substrate 6, the penetrating conductors 61 are not limited in form. In the example of FIGS. 1-3, the penetrating conductors 61 have connecting parts (61a) connecting to the electrodes (E1a) of the component (E1).

In the non-conductor region (NC), the optical waveguide 5 is formed on the first surface (6b) of the support substrate 6. The optical waveguide 5 is formed on the support substrate 6. The optical waveguide 5 includes a core part 51 that transmits an optical signal and a cladding part 52 that surrounds the core part 51. The cladding part 52 is provided around the core part 51 and sandwiches the core part 51 in any direction perpendicular to an extension direction of the core part 51, that is, a light propagation direction in the core part 51. The light propagation direction is the +X direction or −X direction, hereinafter simply collectively referred to as the “X direction.”

The cladding part 52 includes a lower cladding 521 that forms a portion on the support substrate 6 side of the core part 51, and an upper cladding 522 that forms a portion above the lower cladding 521 on a farther side from the support substrate 6 than the lower cladding 521. The upper cladding 522 covers an upper surface (surface on an opposite side with respect to the support substrate 6) and side surfaces of the core part 51. However, a part of the core part 51 is not covered by the upper cladding 522, and is partially exposed from the cladding part 52 above the lower cladding 521.

The core part 51 and the cladding part 52 are each formed using a material having an appropriate refractive index. The core part 51 and the cladding part 52 can each be formed of, for example, an organic material (organic substance), an inorganic material (inorganic substance), or an organic-inorganic mixed material, such as an inorganic polymer, containing an organic component and an inorganic component. Examples of inorganic materials include quartz glass, silicon, and the like, and examples of organic materials include acrylic resins such as polymethylmethacrylate (PMMA), polyimide resins, polyamide resins, polyether resins, epoxy resins, and the like. An optical waveguide 5 formed of an organic substance tends to be lightweight and highly flexible.

The core part 51 and cladding part 52 may be formed of materials different from each other, or may be formed of materials of the same type. However, for the core part 51, a material having a higher refractive index than that used for the cladding part 52 is used so that total reflection of light at an interface between the core part 51 and the cladding part 52 is possible. It is also possible that, after the core part 51 and the cladding part 52 are formed using materials having the same refractive index, the refractive indices of the core part 51 and the cladding part 52 are made different from each other by appropriate processing.

For example, the optical waveguide 5 can be formed on the support substrate 6. For example, the optical waveguide 5 may be bonded to the support substrate 6 by curing the material of the cladding part 52 in a semi-cured state on the support substrate 6. Further, the optical waveguide 5 may be formed separately from the support substrate 6 and fixed to the support substrate 6 with, for example, any adhesive (not illustrated). However, a method for fixing the optical waveguide 5 to the support substrate 6 is not particularly limited. The optical waveguide 5 can be fixed to the support substrate 6 by any modes.

The core part 51 has a first end part (5a) and a second end part (5b), which is an end part on an opposite side with respect to the first end part (5a). In the example of FIGS. 1-3, the first end part (5a) overlaps with the component region (A1) in a plan view. The core part 51 extends from the component region (A1) toward an outer edge of the electrical wiring part 2. The core part 51 is exposed from the cladding part 52 on the lower cladding 521 at the first end part (5a). That is, the upper cladding 522 of the cladding part 52 is not formed to reach an edge part of the lower cladding 521 on the first end part (5a) side. Therefore, at the first end part (5a), not only an end surface of the core part 51 but also the upper and side surfaces of the core part 51 are exposed from the cladding part 52.

At the first end part (5a), the core part 51 is positioned so as to face the light receiving or light emitting part (E1b) of the component (E1) when the wiring substrate 1 is used. Specifically, the core part 51 is positioned such that an upper surface (51a) (see FIG. 2) of the core part 51 and a surface of the light receiving or light emitting surface (E1c) of the component (E1) facing the support substrate 6 side face each other and are optically coupled. In this way, when the wiring substrate 1 is used, the core part 51 and the component (E1) are optically coupled. It is also possible that the optical waveguide with the core part 51 of the optical waveguide exposed at an end part of the optical waveguide is optically coupled by end-face connection with a component with a light receiving or light emitting surface formed on a side surface of the component. On the other hand, an end surface of the core part 51 on the second end part (5b) side is positioned to face and be optically coupled with an optical fiber (F), which is connected to the optical waveguide 5 using a connector (C) when the wiring substrate 1 is used.

Since the optical waveguide 5 is positioned in this way, an optical signal propagated through the optical fiber (F) enters the optical waveguide 5 from the second end part (5b) of the core part 51, and then enters the component (E1) via the light receiving or light emitting part (E1b) from the first end part (5a), and is converted into an electrical signal in the component (E1). On the other hand, an electrical signal input into the component (E1) via the electrodes (E1a) is converted into an optical signal in the component (E1). The optical signal exits from the light receiving or light emitting part (E1b), enters the optical waveguide 5 from the first end part (5a), and exits from the second end part (5b) to the optical fiber (F).

In the present embodiment, the optical wiring part 3 includes the support substrate 6, and the optical waveguide 5 is formed on the support substrate 6. Therefore, it is thought that the first end part (5a) and the second end part (5b) of the core part 51 of the optical waveguide 5 can be easily positioned at positions where they can be optically coupled with the light receiving or light emitting part (E1b) of the component (E1), or the optical fiber (F), with sufficient efficiency. That is, the optical waveguide formed of any material, such as various resins used in the optical wiring part 3, may have high flexibility. Therefore, in Patent Document 1, it may be difficult to position and fix the optical waveguide alone at an appropriate position. As a result, sufficient coupling efficiency may not be obtained in optical coupling between the optical waveguide and an optical component and/or an optical fiber.

In contrast, in the present embodiment, the optical wiring part 3 includes the support substrate 6, and the optical waveguide 5 is formed in the non-conductor region (NC) of the first surface (6b) of the support substrate 6. Therefore, the optical waveguide 5 is formed on the support substrate 6. Therefore, the optical waveguide 5 can be easily positioned at an appropriate position. Therefore, it is thought that the optical waveguide 5 is optically coupled with the component (E1) and the optical fiber (F) with sufficient efficiency. Preferably, the support substrate 6 has a higher rigidity than the optical waveguide 5. It is thought that the optical waveguide 5 can be more easily positioned at an appropriate position. Specifically, the first end part (5a) and the second end part (5b) of the core part 51 of the optical waveguide 5 can be easily positioned at appropriate positions.

In the present embodiment, the support substrate 6 has a thermal expansion coefficient lower than that of the optical waveguide 5. Since the optical waveguide has a thermal expansion coefficient corresponding to its constituent material, the core part may be displaced relative to the combined optical fiber and/or optical component in response to a change in ambient temperature. Therefore, even when the optical waveguide is appropriately positioned relative to the optical fiber and/or optical component, efficiency of optical coupling between the optical waveguide and the optical fiber or optical component may decrease when the wiring substrate is used.

In contrast, in the present embodiment, the support substrate 6 that supports the optical waveguide 5 in the optical wiring part 3 has a lower thermal expansion coefficient than the optical waveguide 5. Therefore, the displacement of the core part 51 of the optical waveguide 5 due to a change in ambient temperature is suppressed. Therefore, it is thought that misalignment between the optical waveguide 5 and the optical fiber (F) and/or the component (E1) in an environment where the temperature changes is suppressed. In this way, according to the present embodiment, it is thought that misalignment between the optical waveguide 5 provided on the wiring substrate 1 and the component (E1) or the like optically coupled to the optical waveguide 5 can be suppressed, and the efficiency of the optical coupling can be improved or a decrease in the efficiency of the optical coupling can be suppressed.

When the core part 51 and the cladding part 52 have different thermal expansion coefficients, the thermal expansion coefficient of the support substrate 6 is lower than an average value of the thermal expansion coefficients of the core part 51 and the cladding part 52. Preferably, the thermal expansion coefficient of the support substrate 6 is lower than the lower of the thermal expansion coefficients of the core part 51 and the cladding part 52. In this way, the support substrate 6 can be formed of any material so as to have a lower thermal expansion coefficient than the optical waveguide 5 and preferably have a higher rigidity than the optical waveguide 5. For example, the support substrate 6 has a higher bending rigidity than the optical waveguide 5. The material of the support substrate 6 is preferably an inorganic material. Examples of the material of the support substrate 6 include glasses such as soda-lime glass, borosilicate glass, and quartz glass; various ceramics such as alumina, silicon nitride, and silicon oxide; and semiconductors such as silicon and germanium.

The thermal expansion coefficient of the optical waveguide 5 is, for example, 10 ppm/° C.-100 ppm/° C. In contrast, the thermal expansion coefficient of the support substrate 6 is 3 ppm/° C.-10 ppm/° C. The bending rigidity of the support substrate 6 is, for example, 1.1 or more times the bending rigidity of the optical waveguide 5, and 2 or less times the bending rigidity of the electrical wiring part 2. It is thought that the optical waveguide 5 can be held such that it can be easily handled and that the optical wiring part 3 can follow the warping of the electrical wiring part 2 to some extent. A thickness of the support substrate 6 is not particularly limited, but may be, for example, about 30 μm or more and 1000 μm or less.

Continuing to refer to FIGS. 2 and 3, an example of a structure of the support substrate 6 in the optical wiring part 3, and an example of a mode in optical coupling and electrical connection between the wiring substrate 1 and the component (E1), will be described. As illustrated in FIGS. 2 and 3, the component (E1) is positioned such that the light receiving or light emitting part (E1b) faces the first end part (5a) of the core part 51 of the optical waveguide 5. Further, the component (E1) is positioned such that the electrodes (E1a) are positioned in a region of the first surface (6b) of the support substrate 6 where the optical waveguide 5 is not formed in a plan view. In particular, in the example of FIG. 2 and the like, the light receiving or light emitting part (E1b) is positioned so as to overlap an exposed portion of the core part 51 in a plan view, and the light receiving or light emitting part (E1b) faces the upper surface (51a) of the core part 51 in the thickness direction (Z direction) of the wiring substrate 1. Part of light propagating in the core part 51 toward the first end part (5a) leaks out of the core part 51 from the upper surface (51a) as evanescent light and enters the light receiving or light emitting part (E1b) of the component (E1). Since the upper surface (51a) faces the light receiving or light emitting surface (E1c) of the component (E1) without intervention of the cladding part 52, it is thought that highly efficient optical coupling is achieved. It is also possible that the optical waveguide with the core part 51 of the optical waveguide exposed at an end part of the optical waveguide is optically coupled by end-face connection with a component with a light receiving or light emitting surface formed on a side surface of the component.

The penetrating conductors 61 illustrated in FIG. 2 have connecting parts (61a), which are to be connected to the electrodes (E1a) of the component (E1), on the first surface (6b) side of the support substrate 6. The term “connected” in “connecting parts to be connected to the electrodes (E1a) of the component (E1)” means being connected only via connecting materials such as connecting bodies of solder (such as the conductive bumps 63) or adhesives (without involving any other structural elements that do not have a connecting function), or being directly connected without anything in between. Then, in the example of FIG. 2, the penetrating conductors 61 are connected to the conductor pads (11a) of the conductor layer 11 via conductive connecting bodies 4 on the second surface (6a) side of the support substrate 6. An electrical signal generated by photoelectric conversion in the component (E1) is output from the electrodes (E1a) via the penetrating conductors 61 to the conductor pads (11a), and is then input to the component (E2) (see FIG. 1) via the conductor layer 11 for processing. On the other hand, an electrical signal output from the component (E2) to the component (E1) is input to the electrodes (E1a) via the conductor pads (11a) and the penetrating conductors 61, and is converted into an optical signal in the component (E1).

In the wiring substrate 1 of the present embodiment, the support substrate 6, on the first surface (6b) of which the optical waveguide 5 is formed, includes the penetrating conductors 61 that can be connected to the component (E1), which is optically coupled to the optical waveguide 5, for example, at the connecting parts (61a) on the first surface (6b) side. The penetrating conductors 61 penetrating the support substrate 6 can be directly connected to the conductor layer 11 of the electrical wiring part 2 on the second surface (6a) side, for example as illustrated in FIG. 2, or can be connected to the conductor layer 11 via any conductor (not illustrated) extending along the second surface (6a). That is, the component (E1) and the electrical wiring part 2 can be connected via the penetrating conductors 61 of the support substrate 6. By the support substrate 6, more specifically by the penetrating conductors 61, the electrodes (E1a) of the component (E1) and the conductors of the electrical wiring part 2 can be electrically and mechanically connected.

In this way, in the wiring substrate 1 of the present embodiment, the penetrating conductors 61, which are exposed on the first surface (6b) side of the support substrate 6 and are electrically and mechanically connected to the component (E1), are included in the conductor region (CA) of the support substrate 6. Then, the optical waveguide 5 including the core part 51 optically coupled to the component (E1) is also formed on the first surface (6b). Therefore, in the wiring substrate 1, portions (the connecting parts (61a) of the penetrating conductors 61 in the example of FIG. 3) that are connected to the electrodes (E1a) of the component (E1) can be easily positioned at predetermined relative positions corresponding to a positional relationship between the electrodes (E1a) and the light receiving or light emitting part (E1b), with respect to the core part 51, which is optically coupled to the light receiving or light emitting part (E1b) (the relative positions of the portions connected to the electrodes (E1a) with respect to a portion of core part 51 that is optically coupled the light receiving or light emitting part (E1b) are hereinafter also simply referred to as the “relative positions”). The predetermined relative positions are positions that allow appropriate optical coupling between the component (E1) and the core part 51 and reliable connection between the component (E1) and the conductor layer 11 to be achieved.

That is, when the optical waveguide 5 is formed on the support substrate 6, in order for the electrodes (E1a) to be connected to the conductor layer 11 without going through the support substrate 6, for example, conductors such as conductor posts (not illustrated) are provided between the conductor layer 11 and the electrodes (E1a). Then, such conductors are to have an appropriate height determined according to a height of the core part 51 relative to the surface (2a) of the electrical wiring part 2, in order achieve the predetermined relative positions with respect to the core part 51. However, since the connecting material 7, the support substrate 6, and the lower cladding 521 of the cladding part 52 are interposed between the electrical wiring part 2 and the core part 51, the required height is likely to vary, and therefore it may be difficult to provide conductors having the required height on the conductor layer 11.

In addition, since the thermal expansion coefficient of such conductors is often different from the thermal expansion coefficient of the support substrate 6 or the cladding part 52, the height of the conductors relative to the core part 51 is likely to vary with changes in ambient temperature. Such thermal expansion-induced variation in the relative positions of the conductors with respect to the core part 51 occurs not only in the Z-direction but also in a direction along the surface of the support substrate 6. When the relative positions with respect to the core part 51 deviate from the predetermined relative positions, it may be possible that the conductor layer 11 and the electrodes (E1a) of the component (E1) are not properly electrically connected or mechanically connected, and the core part 51 and the light receiving or light emitting part (E1b) of the component (E1) are not properly optically coupled.

However, in the present embodiment, the conductor region (CA) of the support substrate 6 includes the penetrating conductors 61 exposed on the first surface (6b) side of the support substrate 6. In particular, in the example of FIG. 2 and the like, the penetrating conductors 61 have the connecting parts (61a) on the first surface (6b) side that are electrically and mechanically connected to the electrodes (E1a) of the component (E1). Only the lower cladding 521 of the cladding part 52 is interposed between the first surface (6b) of the support substrate 6 and the core part 51. Therefore, in the penetrating conductors 61, the portions to be connected to the electrodes (E1a), such as the connecting parts (61a), can be easily positioned at the predetermined relative positions with respect to the core part 51. In addition, it is thought that the portions to be connected to the electrodes (E1a), such as the connecting parts (61a), and the core part 51 displace in conjunction with each other in both the thickness direction of the support substrate 6 and the direction along the surface of the support substrate 6, in response to expansion or contraction of the support substrate 6, even when the ambient temperature changes. Therefore, the relative positions of the portions to be connected to the electrodes (E1a), such as the connecting parts (61a), with respect to the core part 51 are unlikely to fluctuate. Then, the penetrating conductors 61 penetrate the support substrate 6, and thus, can be connected to the conductors included in the electrical wiring part 2, such as the conductor layer 11, on the second surface (6a) side. That is, according to the present embodiment, it is thought that both appropriate optical coupling between an optical component, such as the component (E1) mounted on the wiring substrate, and the core part, and reliable electrical and mechanical connection between the optical component and the conductors in the electrical wiring part are achieved.

Further, according to the present embodiment, compared to a case where the electrodes (E1a) are connected to the conductor layer 11 using conductors such as conductor posts without going through the support substrate 6, it is thought that the mounting of the component (E1) is easier, since the component (E1) does not need to be positioned on tall conductors. Further, according to the present embodiment, it may be possible that the connection pads (the connecting parts (61a) of the penetrating conductors 61 in the example of FIG. 3) connecting to the component (E1) can be miniaturized compared to a case where the electrodes (E1a) are connected to the conductor layer 11 only by using connecting bodies such as solder bumps without using the support substrate 6 or conductors such as conductor posts. That is, in order to connect the component (E1) and the conductor layer 11 using only connecting bodies such as solder bumps, connecting bodies with a height corresponding to a combined thickness of the support substrate 6 and the lower cladding 521 of the cladding part 52 of the optical waveguide 5 are required, and the connecting bodies each occupy an area that increases with the increase in the height of the connecting bodies in a plan view. Therefore, the miniaturization of the connection pads may be hindered. In the present embodiment, since the penetrating conductors 61 exposed on the first surface (6b) side of the support substrate 6 are provided, a distance from the electrodes (E1a) of the component (E1) to the portions such as the connecting parts (61a) connected to the electrodes (E1a) is short, and the height of the connecting bodies (for example, the conductive bumps 63 illustrated in FIG. 2) required for connecting the two is reduced. Therefore, miniaturization of the connection pads connecting to the component (E1), such as the connecting parts (61a) is facilitated.

As illustrated in FIG. 2, the penetrating conductors 61 are formed in the through holes 60 that penetrate the support substrate 6. The penetrating conductors 61 are simplified and each depicted as a single unit in FIG. 1, but may each have a multi-layer structure as illustrated in the enlarged view in FIG. 2. In the example of FIG. 2, the penetrating conductors 61 are each formed of a metal film 611 and a metal pillar 612. The metal film 611 and the metal pillar 612 illustrated in FIG. 2 are formed, for example, of any metal, such as copper or nickel, as a material of the penetrating conductors 61. The metal film 611 is formed on inner wall surfaces of the support substrate 6 exposed in the through holes 60, and on the first surface (6b) and the second surface (6a) of the support substrate 6 around the through holes 60. The metal film 611 can be formed, for example, by electroless plating or sputtering. The metal pillars 612 are formed on the metal film 611. The through-holes 60 are mainly filled by the metal pillars 612. The metal pillars 612 may be formed of a plating film formed by, for example, electrolytic plating using the metal film 611 as a power feeding layer.

The connecting parts (61a) of the penetrating conductors 61 are provided on the first surface (6b) of the support substrate 6 so as to overlap with the through holes 60 in a planar view. The penetrating conductors 61 further each have a connecting part (61b) connected to the conductor layer 11 on the second surface (6a) side. The connecting parts (61b) are provided on the second surface (6a) of the support substrate 6 so as to overlap with the through holes 60 in a planar view. The penetrating conductors 61 protrude from the first surface (6b) of the support substrate 6 at the connecting parts (61a), and protrude from the second surface (6a) at the connecting parts (61b). The connecting parts (61a) and the connecting parts (61b) are wider in a planar view than portions of the penetrating conductors 61 in the through holes 60. The connecting parts (61a) each cover a portion of the first surface (6b), and the connecting parts (61b) each cover a portion of the second surface (6a).

The penetrating conductors 61 include a metal film (61c) that forms the surfaces of the penetrating conductors 61 on the first surface (6b) side along the first surface (6b) of the support substrate 6. Similarly, the penetrating conductors 61 include a metal film (61d) that forms the surfaces of the penetrating conductors 61 on the second surface (6a) side of the support substrate 6. For example, the metal films (61c, 61d) may be electroless plating films or sputtering films containing nickel, palladium, gold, or the like. The metal films (61c, 61d) may prevent corrosion of the surfaces of the connection parts (61a, 61b). Further, the metal films (61c, 61d) may also prevent diffusion of metal components that form the conductive connecting bodies 4 and the conductive bumps 63 into the connecting part s (61a, 61b).

The support substrate 6 illustrated in FIG. 2 includes the conductive bumps 63 formed on the penetrating conductors 61 on the first surface (6b) side. The conductive bumps 63 are formed, for example, using tin-based solder, gold-based solder, or the like. Further, the conductive bumps 63 may also contain metals such as tin, silver, copper, bismuth, zinc, gold, and antimony, either individually or in combination. By the conductive bumps 63 that melt when the component (E1) is mounted, the electrodes (E1a) of the component (E1) and the connecting parts (61a) are electrically and mechanically connected. In the example of FIG. 2, the connecting parts (61a) and the electrodes (E1a) are connected via only the conductive bumps 63 as the connecting bodies.

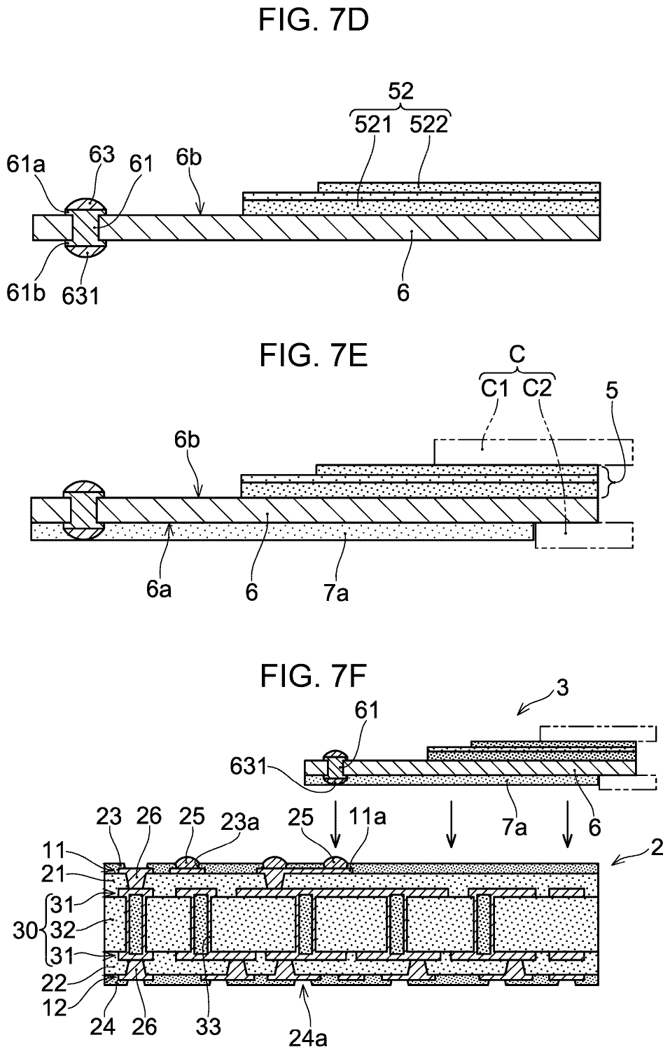

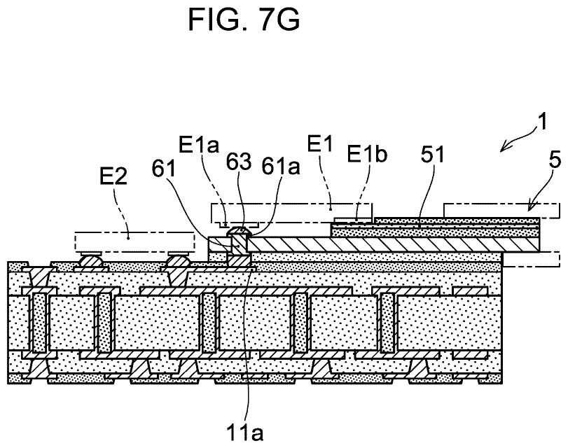

Although not illustrated in FIG. 2, the support substrate 6 may have conductive metals, which contribute to the connection to the electrical wiring part 2, also on the surfaces of the penetrating conductors 61 on the electrical wiring part 2 side before being positioned on the electrical wiring part 2. Such conductive metals (for example, conductive bumps 631 illustrated in FIG. 7D) may be formed of the same material as the conductive bumps 63 on the first surface (6b) side, or may be formed of a material different from that of the conductive bumps 63.

The conductive bumps 63 preferably have an appropriate height so that the conductive bumps 63 and the electrodes (E1a) of the component (E1) come into contact with each other when the component (E1) is mounted, and the core part 51 of the optical waveguide 5 and the light receiving or light emitting part (E1b) of the component (E1) can be appropriately optically coupled. For example, the height of the conductive bumps 63 on the first surface (6b) of the support substrate 6 (the height of the conductive bumps 63 relative to the first surface (6b)) is preferably equal to the height of the lower cladding 521 of the cladding part 52 on the first surface (6b) (the height of the lower cladding 521 relative to the first surface (6b)). Specifically, the height of the conductive bumps 63 on the first surface (6b) is not particularly limited, but is preferably 50% or more and 150% or less of the height of the lower cladding 521 on the first surface (6b). It is thought that, when the conductive bumps 63 have such a height, the electrodes (E1a) of the component (E1) and the penetrating conductors 61 are reliably connected, and the light receiving or light emitting part (E1b) of the component (E1) and the core part 51 of the optical waveguide 5 are optically coupled with sufficient coupling efficiency.

The penetrating conductors 61 in FIG. 2 are connected to the conductor pads (11a), which are conductors in the electrical wiring part 2, via the conductive connecting bodies 4. For example, the conductive connecting bodies 4 are bumps made of a conductive metal formed on the conductor pads (11a), similar to the conductive bumps 25 (see FIG. 1) on the conductor pads (11b), and can be formed of various solders or low-melting-point metals. That is, the conductive connecting bodies 4 may be re-solidified bodies of tin-based solder, gold-based solder, or the like that is supplied onto the conductor pads (11a) and melted by heating when connecting the optical wiring part 3, or metal bodies made of a low-melting-point metal. The formation of the conductive bumps 25 and the supply of the conductive connecting bodies 4 may be performed at the same time, which may improve the efficiency when the wiring substrate 1 is manufactured.

Further, the conductive connecting bodies 4 may also be solidified bodies of various solders such as tin-based or gold-based solders after melting, or metal bodies of a low-melting-point metal, which form the conductive metal bumps (for example, the conductive bumps 631 illustrated in FIG. 7D) provided on the penetrating conductors 61 on the second surface (6a) side of the support substrate 6. These conductive metal bumps may be formed of the same material as the conductive bumps 63 formed on the first surface (6b) side. Therefore, the conductive connecting bodies 4 connecting the penetrating conductors 61 and the conductors in the electrical wiring part 2 such as the conductor pads (11a) may be formed of the same material as the conductive bumps 63 of the optical wiring part 3. When the formation of the conductive bumps 63 and the supply of the metal such as solder of the conductive connecting bodies 4 on the optical wiring part 3 side (the formation of bumps of a conductive metal on the connecting parts (61b)) are performed at the same time, the efficiency when the wiring substrate 1 is manufactured may be improved. The conductive connecting bodies 4 may be solidified bodies of a mixture formed when the bumps of a conductive metal provided on the connecting parts (61b) of the penetrating conductors 61 melt with connecting bodies of solder or the like supplied, for example, in the form of bumps on the conductor pads (11a).

However, the conductive connecting bodies 4 may be formed of a material with different components or composition ratios from the material constituting the conductive bumps 63 or the conductive bumps 25. For example, when the conductive connecting bodies 4 have a melting point higher than the conductive bumps 63 or the conductive bumps 25, the conductive connecting bodies 4 will not remelt when the component (E1) or the component (E2) (see FIG. 1) is mounted, and thus, a decrease in strength of the conductive connecting bodies 4 due to re-melting may be prevented.

In the example of FIG. 2, the optical wiring part 3 is fixed to the electrical wiring part 2 using the connecting material 7. Specifically, the second surface (6a) of the support substrate 6 and the surface (2a) of the electrical wiring part 2 are connected by the connecting material 7. A material forming the connecting material 7 is not particularly limited, but is preferably an insulating material, and more preferably a resin material. One example of such a material is a thermosetting resin. As the material forming the connecting material 7, for example, any insulating adhesive such as an epoxy or acrylic adhesive can be used. Further, the connecting material 7 is preferably formed of a material different from that of the conductive connecting bodies 4. When the connecting material 7 has an insulating property different from that of the conductive connecting bodies 4, it is thought that when the support substrate 6 includes multiple penetrating conductors 61 as illustrated in FIG. 3, short-circuiting between adjacent penetrating conductors 61 is prevented. Further, for example, when the connecting material 7 has a lower elastic modulus than the conductive connecting bodies 4, which are formed of a metal such as solder, it is estimated that a stress caused by, for example, a difference in thermal expansion coefficient is small in the support substrate 6 and the electrical wiring part 2 (specifically, the solder resist 23) connected by the connecting material 7 over a relatively wide range.

When the material forming the connecting material 7 is a resin material, a glass transition temperature of the connecting material 7 is preferably 50° C. to 200° C. The thermal expansion coefficient of the connecting material 7 is, for example, 30 ppm/° C. to 200 ppm/° C. The thickness of the connecting material 7 is not particularly limited, but is about 5 μm to 200 μm.

The connecting material 7 may contain particles in the material, specifically, inorganic particles, metal particles, resin particles, and the like. Sizes of the particles contained in the connecting material 7 are not particularly limited, but are, for example, about 0.1 μm to 20 μm. By containing particles in the connecting material 7, rigidity of the connecting material 7 is improved and the connecting material 7 is imparted with heat resistance.

As illustrated in FIG. 3, the optical waveguide 5 in the example of FIGS. 1-3 includes multiple core parts 51. Although the core parts 51 are covered by the cladding part 52 in a plan view, in FIG. 3, the core parts 51 are drawn with solid lines for ease of viewing. The multiple core parts 51 are formed side by side along a direction intersecting the light propagation direction (X direction) in the core parts 51. Then, in the example of FIG. 3, spacings between the multiple core parts 51 increase as they approach the second end part (5b) from the first end part (5a). Therefore, a pitch of the core parts 51 at the second end part (5b) is larger than a pitch at the first end part (5a). For example, it may be possible that multiple optical fibers optically coupled to the core parts 51 at the second end part (5b) cannot be formed at a pitch as small as a pitch of multiple light receiving or light emitting parts (E1b) (see FIG. 2) provided in the component (E1). In the example of FIG. 3, since the multiple core parts 51 are formed at a larger pitch at the second end part (5b) than at the first end part (5a), it is thought that the core parts 51 and the component (E1) (see FIG. 2) or the optical fibers are appropriately optically coupled at the first end part (5a) and the second end part (5b) without requiring a separate pitch conversion means.

In the example of FIG. 3, the conductor region (CA) of the support substrate 6 includes multiple penetrating conductors 61. The multiple penetrating conductors 61 are formed in a row along a direction substantially perpendicular to the X direction. In the multiple penetrating conductors 61, the connecting parts (61a) respectively cover the through holes 60 in which the penetrating conductors 61 are formed. The multiple penetrating conductors 61 are all provided in a region (the conductor region (CA)) other than the non-conductor region (NC) (where the optical waveguide 5 is formed) on the first surface (6b) of the support substrate 6 in a plan view. Therefore, the connecting parts (61a) of the penetrating conductors 61 can be connected to the component (E1) (see FIG. 2) without being interfered with by the optical waveguide 5.

In the example of FIGS. 1-3, as illustrated in FIGS. 2 and 3, the entire component region (A1) overlaps with the support substrate 6 in a plan view. That is, the component region (A1) does not overlap with a region of the surface (2a) of the electrical wiring part 2 that is not covered by the support substrate 6. The region of the surface (2a) that is not covered by the support substrate 6 does not have conductor pads that are directly connected to the component (E1). On the other hand, the multiple penetrating conductors 61 and the connecting parts (61a) thereof are all positioned in the component region (A1) in a planar view. Preferably, in the wiring substrate 1, conductor pads that are respectively directly connected to the multiple electrodes (E1a) of the component (E1) are all provided in the support substrate 6 as the connecting parts (61a) of the penetrating conductors 61. In this way, when the conductor pads connected to the component (E1) are all provided in the support substrate 6, it is thought that all the electrodes (E1a) of the component (E1) are easily and appropriately electrically and mechanically connected to the conductors in the electrical wiring part 2.

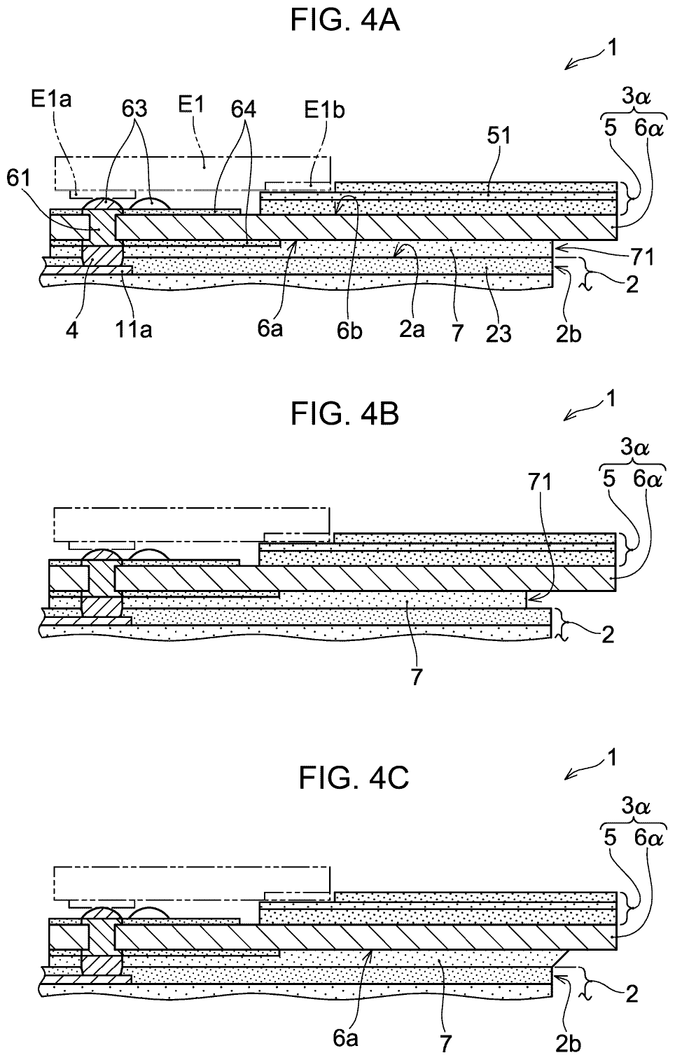

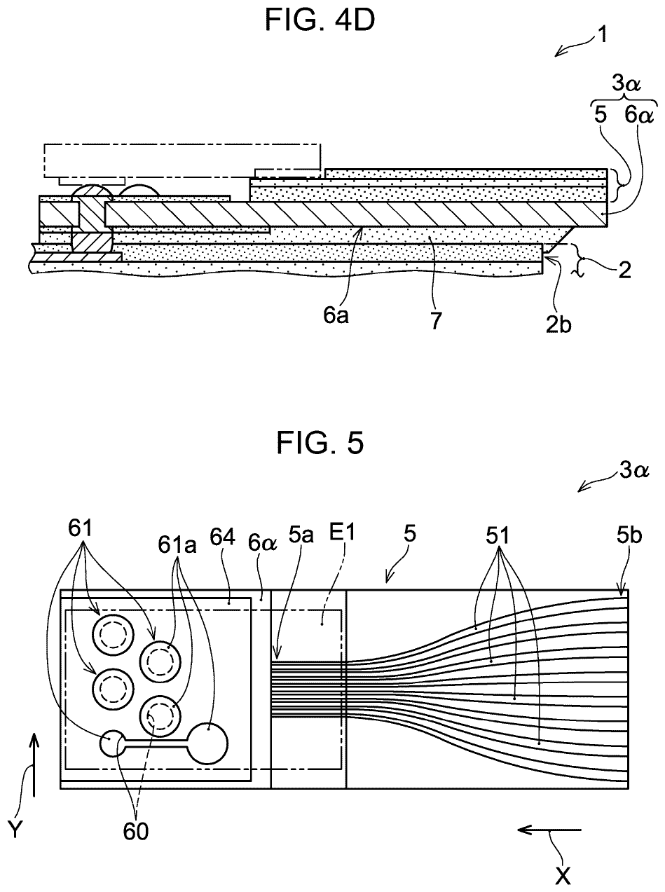

FIGS. 4A-4D each illustrate a state in which an optical wiring part (3α), which is another example of the optical wiring part in the wiring substrate of the embodiment, is connected to the surface (2a) of the electrical wiring part 2. Then, FIG. 5 illustrates an example of the optical wiring part (3α) in FIG. 4A in a plan view. The optical wiring part (3α) in the example of FIGS. 4A-4D and 5 includes a support substrate (6α) that includes penetrating conductors 61, similar to the support substrate 6 of the optical wiring part 3 in the example of FIG. 1 and the like. Then, the support substrate (6α) in the example of FIGS. 4A-4D and 5 further includes a solder resist 64 on each of the first surface (6b) and the second surface (6a). The solder resist 64 is formed around the penetrating conductors 61 on each of the first surface (6b) and the second surface (6a).

The solder resist 64 is formed of any insulating resin. The solder resist 64 can be formed of the same material as the material forming the solder resist 23 included in the electrical wiring part 2, for example, a photosensitive epoxy resin or polyimide resin, or the like. When the solder resist 64 is formed around the penetrating conductors 61, it is thought that a short circuit failure between the multiple penetrating conductors 61 due to the conductive bumps 63 or the conductive connecting bodies 4 is prevented. The solder resist 64 may be formed only on either the first surface (6b) or the second surface (6a). It is thought that a short circuit failure on at least one of the first surface (6b) and the second surface (6a) is prevented.

In the example of FIG. 4A, the connecting material 7 connecting the electrical wiring part 2 and the support substrate (6α) is formed such that an outer edge of the electrical wiring part 2 and an outer edge of the connecting material 7 coincide with each other near an end part of the electrical wiring part 2. That is, the connecting material 7 is formed such that an end surface (2b) of the electrical wiring part 2 and an end surface 71 of the connecting material 7 are substantially flush with each other. The connecting material 7 may be formed up to an edge part of the wiring substrate 1 as in the example of FIG. 4A.

In the example of FIG. 4B, the connecting material 7 is formed up to an inner side of an outer edge of the wiring substrate 1 such that the end surface 71 is positioned on an inner side the outer edge of the electrical wiring part 2. The end surface 71 of the connecting material 7 in the example of FIG. 4B is recessed inward relative to the end surface of the electrical wiring part 2. A distance between the end surface 71 of the connecting material 7 and the end part of the electrical wiring part 2 is preferably 10 mm or less.

The connecting material 7 may extend beyond the edge part of the wiring substrate 1 and extend over the support substrate (6α) on an outer side of the electrical wiring part 2 as in the examples of FIGS. 4C and 4D. In the example of FIG. 4C, the connecting material 7 protrudes from the outer edge of the electrical wiring part 2 and extends over a portion of the optical wiring part (3α) that protrudes from the outer edge of the electrical wiring part 2. The connecting material 7 covers a portion near the electrical wiring part 2 at a portion of the second surface (6α) of the support substrate (6α) that protrudes from the outer edge of the electrical wiring part 2. Therefore, it is thought that the support substrate (6α) and the optical waveguide 5 are more firmly connected to the electrical wiring part 2. A distance by which the connecting material 7 protrudes from the outer edge of the electrical wiring part 2 is preferably within 10 mm.

In the example of FIG. 4D, the connecting material 7 extends over both the support substrate (6α) and the end surface of the wiring substrate 1 on an outer side of the electrical wiring part 2. That is, the connecting material 7 in FIG. 4D extends over not only the support substrate (6α) but also the end surface (2b) of the electrical wiring part 2 on an outer side of the electrical wiring part 2. At the edge part of the wiring substrate 1, the connecting material 7 covers a portion near the electrical wiring part 2 at a portion of the second surface (6a) of the support substrate (6α) that protrudes from the outer edge of the electrical wiring part 2, and a portion of the end surface (2b) of the electrical wiring part 2. Therefore, it is thought that the optical wiring part (3α) including the support substrate (6α) and the optical waveguide 5 and the electrical wiring part 2 are more firmly connected. In the wiring substrate 1 that includes the support substrate 6 and does not include a solder resist as illustrated in FIGS. 1-3 referenced above, the connecting material 7 may be formed in any of the modes illustrated in FIGS. 4A-4D.

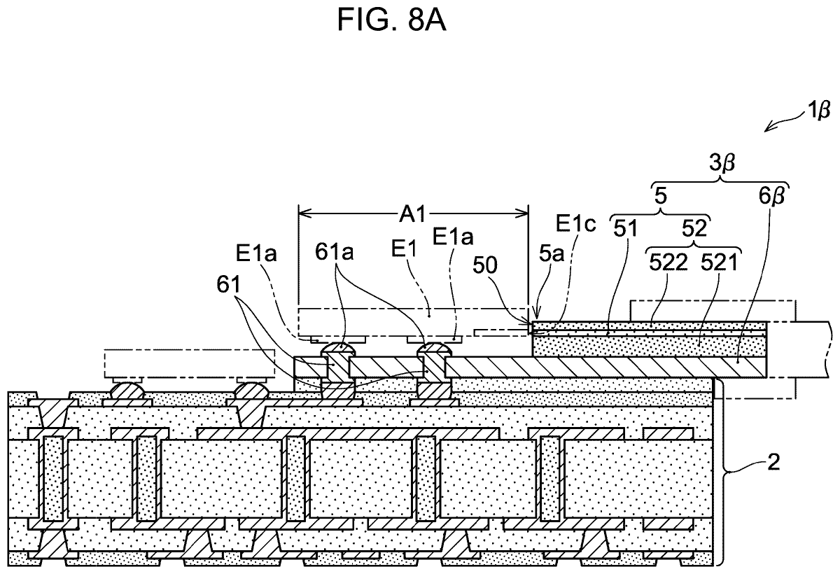

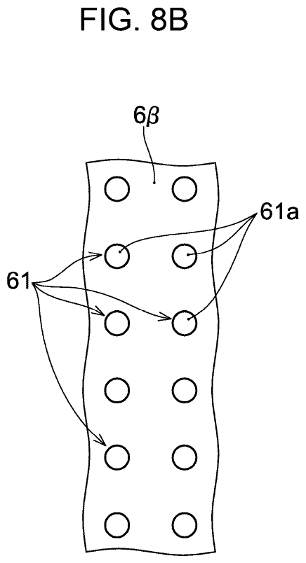

The support substrate (6α) illustrated in FIGS. 4A-4D and 5 includes multiple penetrating conductors 61, similar to the support substrate 6 illustrated in FIG. 3. Then, in the support substrate (6α), the multiple penetrating conductors 61 are formed in a zigzag pattern in a predetermined direction in a plan view. The multiple penetrating conductors 61 illustrated in FIG. 5 are formed in a zigzag or staggered pattern in the Y direction, which is substantially perpendicular to the X direction, which is the propagation direction of light propagating through the core part 51. That is, the multiple penetrating conductors 61 formed in the Y direction are formed at alternating positions in one row across two adjacent rows in the X direction. The penetrating conductors that are closest to each other in the Y direction are formed in different rows. When the multiple penetrating conductors 61 are formed in a zigzag or staggered formation, a formation range of the penetrating conductors 61 in a specific direction (the Y direction in the example of FIG. 5) is narrowed, and more penetrating conductors 61 can be formed while reducing the possibility of a short circuit occurring between them. It is also possible that the multiple penetrating conductors 61 are formed in a lattice formation (see FIG. 8B). Spacings between the multiple penetrating conductors 61 may be regular or irregular, or some may be regular and the rest may be irregular. The penetrating conductors 61 can be arbitrarily formed.

In the example of FIG. 5, among the multiple penetrating conductors 61, a penetrating conductor 61 at a lower end in FIG. 5 has its connection part (61a) in a position that does not overlap with the through hole 60. That is, the connecting part (61a) of the penetrating conductor 61 at the lower end is provided at a position offset from the through hole 60 in a plan view. When the connecting part (61a) is provided in this manner, it may be possible that a degree of freedom in forming the conductor pads (11a) (see FIG. 4A) of the electrical wiring part 2 relative to the formation of the electrodes (E1a) (see FIG. 4A) of the component (E1) mounted on the wiring substrate 1 is improved.

Further, in the example of FIG. 5, a width of each of the multiple core parts 51 increases from the first end part (5a) toward the second end part (5b). Therefore, the width of each core part 51 at the second end part (5b) is larger than the width at the first end part (5a). It may be possible that a width of each of the multiple optical fibers optically coupled to the core parts 51 at the second end part (5b) is larger than a width of each of the multiple light receiving or light emitting parts (E1b) (see FIG. 4A) provided in the component (E1). In the example of FIG. 5, since each core part 51 has a width larger at the second end part (5b) than at the first end part (5a), it is thought that the core parts 51 and the component (E1) or the optical fibers are appropriately optically coupled with little optical loss at the first end part (5a) and the second end part (5b).

The core part 51 of the optical waveguide 5 included in the wiring substrate of the embodiment may have a thickness that increases from the first end part (5a) to the second end part (5b) in addition to the width that increases from the first end part (5a) to the second end part (5b).

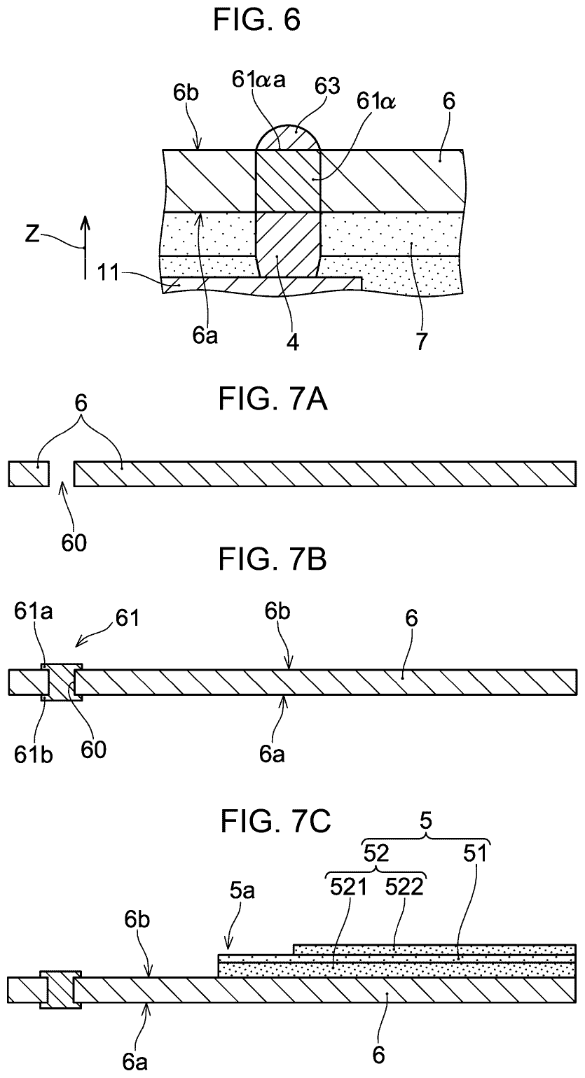

FIG. 6 illustrates a penetrating conductor (61α), which is another example of a penetrating conductor in the wiring substrate of the embodiment, together with the support substrate 6 and the connecting material 7. The penetrating conductor (61α) does not include the metal film 611 and the metal pillar 612 included in the penetrating conductor 61 illustrated in FIG. 2. The penetrating conductor (61α) is formed of a single element. For example, the penetrating conductor (61α) may be a solidified body of a conductive paste formed of an epoxy resin containing conductive particles of silver or copper or the like. The penetrating conductor (61α) in the example of FIG. 6 does not protrude from the first surface (6b) and the second surface (6a) of the support substrate 6. Two end surfaces of the penetrating conductor (61α) that intersect with the Z direction are substantially flush with the first surface (6b) or the second surface (6a). The end surface of the penetrating conductor (61α) on the first surface (6b) side of the support substrate 6 functions as a connecting part (61αa) that is connected to the component (E1) (see FIG. 1). A conductive bump 63 is provided on the end surface on the first surface (6b) side. On the other hand, the end surface of the penetrating conductor (61α) on the second surface (6a) side of the support substrate 6 is connected to the conductor layer 11 via a conductive connecting body 4. As in the example of FIG. 6, in the wiring substrate of the embodiment, a penetrating conductor included in a substrate included in the optical wiring part does not have to protrude from both sides of the substrate. And, a connecting part of a penetrating conductor connected to a component that is optically coupled to the optical waveguide may be formed by an end surface of the penetrating conductor that is substantially flush with a surface of the substrate.

Next, an example of a method for manufacturing the wiring substrate of the embodiment is described with reference to FIGS. 7A-7G, using a case where the wiring substrate 1 of FIG. 1 is manufactured as an example.

As illustrated in FIG. 7A, for example, a glass plate, a ceramic plate, or a semiconductor substrate of silicon or the like, is prepared as the support substrate 6. For example, a support substrate 6 having a thickness of about 0.05 mm or more and 0.7 mm or less is prepared. Then, holes are formed in the support substrate 6 by drilling, laser processing, etching, or the like. Diameters of holes formed in the support substrate 6 are not particularly limited. However, through holes 60 having hole diameters of about 0.05 mm to 0.2 mm are formed.

As illustrated in FIG. 7B, the penetrating conductors 61 are formed in the through holes 60 of the support substrate 6. In the example of FIG. 7B, the penetrating conductors 61 each having a connecting part (61a) and a connecting part (61b) are formed. For example, the penetrating conductors 61 are formed by forming a metal film by electroless plating or the like on inner wall surfaces of the through holes 60 and on the entire first surface (6b) and second surface (6a) of the support substrate 6, and then forming a plating film by electrolytic plating using this metal film as a power feeding layer. Unwanted metal films and plating films on the surfaces of the support substrate 6 are removed, for example, by wet etching. The connecting parts (61a) are formed by the metal film and plating film remaining on the first surface (6b) of the support substrate 6. Although not illustrated in FIG. 7B, when the penetrating conductors 61 include the metal films (61c, 61d) as in the example of FIG. 2, the metal films (61c, 61d) are further formed by electroless plating or sputtering using nickel, palladium, gold, or the like. The penetrating conductors in the wiring substrate of the embodiment may also be formed by filling the through holes 60 with a conductive paste made of an epoxy resin or the like containing conductive particles such as silver particles and then solidifying the conductive paste. In this case, the penetrating conductors (61a) in the example illustrated in FIG. 6 can be formed.

As illustrated in FIG. 7C, the optical waveguide 5 is formed on the first surface (6b) of the support substrate 6. Specifically, first, the lower cladding 521 of the cladding part 52 is formed. For example, a constituent material of the cladding part 52, which is made of a resin, such as PMMA, is molded into a film and then thermocompression bonded onto the support substrate 6. Further, the core part 51 is formed on the lower cladding 521. The core part 51 is formed, for example, using a resin material, such as PMMA, as a constituent material of the core part 51. For example, the constituent material of the core part 51 is molded into a film and thermocompression bonded onto the entire surface of the lower cladding 521, and is patterned into desired shape and number of core parts 51 by photolithography. The lower cladding 521 may alternatively be formed by applying a resin material by spin coating instead of using a film.

Further, the upper cladding 522 is formed on the lower cladding 521 and the core part 51. For example, similar to the formation of the lower cladding 521, a constituent material of the upper cladding 522, such as PMMA, is molded into a film and then thermocompression bonded onto the lower cladding 521 and the core part 51. As a result, the cladding part 52 including the lower cladding 521 and the upper cladding 522 is formed. After that, a part of the upper cladding 522 on the first end part (5a) side of the core part 51 is removed by photolithography. The upper cladding 522 may alternatively be formed by applying a resin material by spin coating instead of using a film. The optical waveguide 5 including the core part 51 and the cladding part 52, with a portion at the first end part (5a) side of the core part 51 exposed, is completed on the support substrate 6. The optical waveguide 5 may also be formed using other methods for forming an optical waveguide, such as an imprinting method or a photobleaching method, instead of the method using photolithography.

As illustrated in FIG. 7D, the conductive bumps 63 are formed on surfaces of the penetrating conductors 61. In the example of FIG. 7D, the conductive bumps 631 are formed on surfaces of the connecting parts (61b). The conductive bumps (63, 631) are formed, for example, by supplying solder balls or solder paste of tin-based solder, gold-based solder, or the like, and re-solidifying the solder balls or solder paste after melting by heating. The conductive bumps (63, 631) are not limited to this method, and may be formed by electroless plating or the like, and can be formed using any method. For example, the conductive bumps 63 are formed having a height from the first surface (6b) of the support substrate 6 equal to or less than the height of the lower cladding 521 of the cladding part 52 from the first surface (6b), specifically, 50% or more and 100% or less of the height of the lower cladding 521. Through the above processes, the optical wiring part 3 is completed.

As illustrated in FIG. 7E, a connecting material layer (7a) is formed on the second surface (6a) of the support substrate 6. The connecting material layer (7a) is formed by supplying the connecting material 7 (see FIG. 1) for fixing the support substrate 6 to the electrical wiring part 2 (see FIG. 1) to the second surface (6a). For example, the connecting material 7 molded in a film shape is laminated on the second surface (6a). The connecting material layer (7a) is formed, for example, using any insulating adhesive such as an epoxy-based or acrylic-based adhesive.

When necessary, a connector (C) is provided such that the optical waveguide 5 and the support substrate 6 are sandwiched between an upper housing (C1) and a lower housing (C2). For example, the upper housing (C1) is attached to the optical waveguide 5, the lower housing (C2) is attached to the support substrate 6, and the upper housing (C1) and the lower housing (C2) are further fitted together.

As illustrated in FIG. 7F, the electrical wiring part 2 is prepared. The electrical wiring part 2 is prepared, for example, using a general method for forming a build-up wiring substrate including a core substrate. For example, the core substrate 30 is formed by forming the through-hole conductors 33 in a double-sided copper-clad laminate including the insulating layer 32, and by forming the conductor layers 31 using a subtractive method. Then, the insulating layers (21, 22) and the conductor layers (11, 12), as well as the via conductors 26, are formed by thermocompression bonding of insulating resin films onto both sides of the core substrate 30 and forming the conductor layers using a semi-additive method. Further, the solder resists (23, 24) are formed by laminating an epoxy resin, a polyimide resin, or the like, or coating with these resins, and the openings (23a, 24a) are formed, for example, by photolithography. Then, the conductive bumps 25 are formed in the openings (23a) by forming tin-based solder balls and performing a reflow treatment.

Then, as illustrated in FIG. 7F, the optical wiring part 3 is positioned on the electrical wiring part 2. The optical wiring part 3 is aligned such that the penetrating conductors 61 are placed on the conductive bumps 25 on the conductor pads (11a) of the conductor layer 11. Then, for example, by a heat treatment, the optical wiring part 3 and the electrical wiring part 2 are connected. For example, by a reflow treatment, the conductive bumps 25 on the conductor pads (11a) are fused with the conductive bumps 631 of the support substrate 6, and become the conductive connecting bodies 4 (see FIG. 1), which are re-solidified, thereby connecting the penetrating conductors 61 to the conductor pads (11a). On the other hand, the connecting material layer (7a) is also softened by heating, and connects the solder resist 23 and the support substrate 6.

The formation of the connecting material layer (7a) before connecting the optical wiring part 3 to the electrical wiring part 2 may be omitted. That is, it is also possible that, without the connecting material layer (7a), first, for example, only the connection between the penetrating conductors 61 and the conductor pads (11a) is performed by a reflow treatment. After that, the support substrate 6 and the solder resist 23 may be bonded together by injection of the connecting material 7 (see FIG. 1) into a gap between the electrical wiring part 2 and the optical wiring part 3, and a curing treatment by heating or the like. Through the above processes, the wiring substrate 1 of FIG. 1 is completed.

When the wiring substrate 1 is used, as illustrated in FIG. 7G, the component (E1) including an optical element is mounted. The component (E2) may be mounted together with the component (E1). The electrodes (E1a) of the component (E1) are connected to the connecting parts (61a) of the penetrating conductors 61 by the conductive bumps 63 that melt during mounting. On the other hand, the light receiving or light emitting part (E1b) of the component (E1) is optically coupled to the exposed portion of the core part 51 of the optical waveguide 5. According to the present embodiment, it is thought that both appropriate optical coupling between the component (E1) and the core part 51 and reliable electrical and mechanical connection between the component (E1) and the conductor pads (11a) are achieved.

FIG. 8A illustrates a wiring substrate (1β), which is a modified example of the wiring substrate of the embodiment. The wiring substrate (1β) includes an optical wiring part (3β) having a structure similar to that of the optical wiring part 3 included in the wiring substrate 1 of FIG. 1 and the like. The optical waveguide 5 included in the optical wiring part (3β) differs from the optical waveguide 5 illustrated in FIG. 1 and the like in that the core part 51 is not exposed from the cladding part 52 above the lower cladding 521 at the first end part (5a). The core part 51 in the example of FIG. 8A is covered by the upper cladding 522 even at the first end part (5a), and only an end surface thereof is exposed to a side surface 50 of the optical waveguide 5 together with the end surface of the cladding part 52. The end surface of the core part 51 exposed on the side surface 50 is positioned to face the light receiving or light emitting surface (E1c) of the component (E1) optically coupled to the core part 51. The component (E1) is positioned on an extension line from the first end part (5a) of the optical waveguide 5. Therefore, the component region (A1) is positioned laterally to the optical waveguide 5 and does not overlap the optical waveguide 5 even partially in a plan view. The end surface of the core part 51 exposed on the side surface 50 of the optical waveguide 5 faces the component region (A1) and is optically coupled to the light receiving or light emitting surface (E1c) of the component (E1) by butt coupling.

A support substrate (6β) included in the optical wiring part (3β) in the example of FIG. 8A includes multiple penetrating conductors 61, similar to the support substrate (6α) in the example of FIG. 5 and the like. The multiple penetrating conductors 61 included in the support substrate (6β) are formed in a lattice (or grid or matrix) pattern as illustrated in FIG. 8B, and respectively have the connecting parts (61a) for connecting to the component (E1). It may be possible to connect more electrodes (E1a) of the component (E1) to the conductors in the wiring substrate (1β) in a limited region. Except for the points described above, the wiring substrate (1β) illustrated in FIG. 8A has substantially the same structure and is formed of substantially the same structural elements as the wiring substrate 1 in the example of FIG. 1 and the like. Structural elements similar to the structural elements included in FIG. 1 and the like are indicated using the same reference numeral symbols as in FIG. 1 and the like or are omitted as appropriate in FIG. 8A, and repetitive descriptions are omitted.

The wiring substrate of the embodiment is not limited to those having the structures illustrated in the drawings and those having the structures, shapes, and materials exemplified herein. The wiring substrate of the embodiment, and in particular, the electrical wiring part, may have any layered structure. For example, the electrical wiring part may be a coreless substrate that does not include a core substrate, and includes any number of conductor layers and insulating layers. It is also possible that the conductor pads (11b) are not formed.

Japanese Patent Application Laid-Open Publication No. 2008-129385 describes an optical component mounting substrate, on a surface of which an optical waveguide is mounted. The optical waveguide having a core part and a cladding layer is formed on an interlayer insulating layer exposed on a surface of a wiring substrate. The optical waveguide is positioned such that an end part of the core part is optically coupled to a light emitting part (or light receiving part) of an optical semiconductor element mounted on the wiring substrate. The optical semiconductor element is mounted by connecting bumps thereof to connecting parts of wiring patterns of the wiring substrate.

In the substrate described in Japanese Patent Application Laid-Open Publication No. 2008-129385, it may be possible that the optical waveguide, which is formed of a polyimide resin, an epoxy resin, or the like, cannot be appropriately positioned at a predetermined position on the wiring substrate. In such cases, it is thought that the core part of the waveguide and the light emitting part (or light receiving part) of the optical semiconductor element are not optically coupled with sufficient efficiency. Further, expansion or contraction of the interlayer insulating layer can cause misalignment between the optical semiconductor element and the waveguide, potentially reducing the efficiency of the optical coupling. Further, misalignment is also likely to occur in a thickness direction of the substrate between the optical semiconductor element, which is positioned on the interlayer insulating layer via wiring patterns, connecting parts formed of plating metal, and bumps, and the optical waveguide, which is positioned on the interlayer insulating layer, and this may further reduce the efficiency of the optical coupling.

A wiring substrate according to an embodiment of the present invention includes: an electrical wiring part that includes insulating layers and conductor layers; an optical wiring part that is placed on one surface of the electrical wiring part; and a component region where a component can be positioned on the optical wiring part. The optical wiring part includes: an optical waveguide that includes a core part and a cladding part; and a support substrate that includes a conductor region, which has a conductor, and a non-conductor region, and that has a first surface on a side where the component is positioned and a second surface on a side facing the electrical wiring part. The support substrate has a thermal expansion coefficient lower than a thermal expansion coefficient of the optical waveguide. In the non-conductor region, the optical waveguide is formed on the first surface of the support substrate. The conductor region includes a penetrating conductor penetrating between the first surface of the support substrate and the second surface of the support substrate.

According to an embodiment of the present invention, it may be possible to suppress misalignment between the optical waveguide of the optical wiring part of the wiring substrate and the optical component that is optically coupled to the optical waveguide, thereby improving the coupling efficiency or suppressing a decrease in the coupling efficiency. Further, it may be possible that the mounting of the optical component onto the wiring substrate is facilitated.

Obviously, numerous modifications and variations of the present invention are possible in light of the above teachings. It is therefore to be understood that within the scope of the appended claims, the invention may be practiced otherwise than as specifically described herein.

1. A wiring substrate, comprising:
an electrical wiring part comprising a plurality of insulating layers and a plurality of conductor layers; and
an optical wiring part positioned on a surface of the electrical wiring part and comprising a support substrate and an optical waveguide such that the optical wiring part has a component region configured to position a component on the optical wiring part and the optical waveguide includes a core part and a cladding part,
wherein the support substrate in the optical wiring part has a thermal expansion coefficient lower than a thermal expansion coefficient of the optical waveguide and includes a conductor region and a non-conductor region such that the optical waveguide is formed on a surface of the support substrate in the non-conductor region and the optical wiring part includes at least one penetrating conductor penetrating through the support substrate in the conductor region.

2. The wiring substrate according to claim 1, wherein the at least one penetrating conductor in the optical wiring part has a connecting part configured to connect to the component optically coupled to the core part of the optical waveguide.

3. The wiring substrate according to claim 1, further comprising:
a conductive bump formed on the at least one penetrating conductor.

4. The wiring substrate according to claim 3, wherein the cladding part of the optical wave guide in the optical wiring part includes a lower cladding formed on the support substrate and upper cladding formed on the core part such that the core part has a portion exposed from the upper cladding part such that a height of the conductive bump from the surface of the support substrate is equal to or less than a height of the lower cladding from the surface of the support substrate.

5. The wiring substrate according to claim 1, wherein the electrical wiring part has a conductor exposed on the surface of the electrical wiring part such that the at least one penetrating conductor is connected to the conductor.

6. The wiring substrate according to claim 5, further comprising:
a conductive bump formed on the at least one penetrating conductor; and
a conductive connecting body connecting the at least one penetrating conductor and the conductor and formed of a material that is same as a material of the conductive bump.

7. The wiring substrate according to claim 5, further comprising:
a conductive connecting body connecting the at least one penetrating conductor and the conductor,
wherein a second surface of the support substrate and the surface of the electrical wiring part are connected by a connecting material formed of a material that is different from a material of the conductive connecting body.

8. The wiring substrate according to claim 1, wherein the component region of the optical wiring part entirely overlaps with the support substrate.

9. The wiring substrate according to claim 1, wherein the at least one penetrating conductor in the optical wiring part includes a metal film forming a surface of the at least one penetrating conductor along the surface of the support substrate.

10. The wiring substrate according to claim 1, wherein the support substrate in the optical wiring part includes a solder resist formed around the at least one penetrating conductor on at least one of the surface of the support substrate and a second surface of the support substrate on an opposite side with respect to the surface of the support substrate.

11. The wiring substrate according to claim 1, wherein the at least one penetrating conductor in the conductor region of the support substrate in the optical wiring part comprises a plurality of penetrating conductors such that the plurality of penetrating conductors is formed in a zigzag pattern in a predetermined direction.

12. The wiring substrate according to claim 5, wherein the support substrate in the optical wiring part and the electrical wiring part are connected by a connecting material formed to an edge part of the electrical wiring part.

13. The wiring substrate according to claim 5, wherein the support substrate in the optical wiring part and the electrical wiring part are connected by a connecting material formed to an inner side of the electrical wiring part.

14. The wiring substrate according to claim 5, wherein the support substrate in the optical wiring part and the electrical wiring part are connected by a connecting material such that the connecting material protrudes from an edge part of the electrical wiring part and extends over the support substrate in the optical wiring part.

15. The wiring substrate according to claim 5, wherein the support substrate in the optical wiring part and the electrical wiring part are connected by a connecting material such that the connecting material protrudes from an edge part of the electrical wiring part and extends over the electrical wiring part and the support substrate in the optical wiring part.

16. The wiring substrate according to claim 2, further comprising:
a conductive bump formed on the at least one penetrating conductor.

17. The wiring substrate according to claim 16, wherein the cladding part of the optical wave guide in the optical wiring part includes a lower cladding formed on the support substrate and upper cladding formed on the core part such that the core part has a portion exposed from the upper cladding part such that a height of the conductive bump from the surface of the support substrate is equal to or less than a height of the lower cladding from the surface of the support substrate.

18. The wiring substrate according to claim 2, wherein the electrical wiring part has a conductor exposed on the surface of the electrical wiring part such that the at least one penetrating conductor is connected to the conductor.

19. The wiring substrate according to claim 18, further comprising:
a conductive bump formed on the at least one penetrating conductor; and
a conductive connecting body connecting the at least one penetrating conductor and the conductor and formed of a material that is same as a material of the conductive bump.

20. The wiring substrate according to claim 18, further comprising:
a conductive connecting body connecting the at least one penetrating conductor and the conductor,
wherein a second surface of the support substrate and the surface of the electrical wiring part are connected by a connecting material formed of a material that is different from a material of the conductive connecting body.
